(19) United States
(12) Patent Application Publication
(10) Pub. No.: US 2025/0294712 A1
(43) Pub. Date: Sep. 18, 2025

(54) POWER ELECTRONICS MODULE WITH INTEGRATED HEAT SINK

(71) Applicant: Caterpillar Inc., Peoria, IL (US)

(72) Inventors: Adam J. ADEEB, Naperville, IL (US); Adrian Stefan SPANOCHE, Yorkville, IL (US); Ali AZERI, Redondo Beach, CA (US)

(73) Assignee: Caterpillar Inc., Peoria, IL (US)

(21) Appl. No.: 18/602,604

(22) Filed: Mar. 12, 2024

(51) Int. Cl. H05K 7/20; H02M 3/00; H02M 7/00

(52) U.S. Cl. CPC H05K 7/209; H02M 3/003; H02M 7/003

(57) ABSTRACT

A power electronics module may be configured to control electrical power in multiple phases. The power electronics module may include a capacitor with a casing having multiple panels defining a box-shaped enclosure. The power electronics module may include one or more heat sinks disposed on an exterior of the casing, the one or more heat sinks having first planar surfaces, disposed on one or more of the panels, and second planar surfaces opposite the first planar surfaces. The power electronics module may include a plurality of power switching modules electrically connected to the capacitor and disposed on the second planar surfaces of the one or more heat sinks, the plurality of power switching modules configured to control electrical power flow in respective phases of the multiple phases.

### TECHNICAL FIELD

The present disclosure relates generally to electrical systems and, for example, to a power electronics module with an integrated heat sink.

### BACKGROUND

Power electronics modules are used in a variety of machines and systems to provide control and/or conversion of electrical power. For example, power electronics modules may be integrated into electrical systems used in electric vehicles, diesel-electric machines, battery-electric machines, or renewable energy systems, among other examples. A power electronics module may include a combination of semiconductor devices and control circuitry to facilitate the efficient conversion, regulation, and distribution of electrical power. Furthermore, a power electronics module may include a capacitor that acts as an energy storage device and facilitates voltage regulation, filtering, and/or transient suppression to improve overall power quality. Without efficient thermal management, heat generated in the power electronics module (e.g., by the semiconductor devices) may harm the sensitive semiconductor devices and associated control circuitry as well as harm the capacitor by reducing its capacitance and/or power density. Accordingly, a performance of the power electronics module may suffer due to excessive heat.

U.S. Pat. No. 10,932,396 (the '396 patent) discloses a power module that can include a heat sink module to provide active cooling to a capacitor and transistors of the power module. The power module can be one power module of a multiple phase inverter module disposed within a drive train unit of an electric vehicle.

The power module of the '396 patent is not a multiple-phase power module. Rather, the '396 patent indicates that the power module can couple with two other power modules in a triplet configuration to form a three-phase inverter module. Accordingly, the heat sink module of the '396 patent, which is used in a single-phase power module, is inapplicable to a multiple-phase power electronics module. The spatial arrangement and thermal characteristics of components in a multiple-phase power electronics module differ from that of a single-phase module. Thus, relative to a single-phase module, a multiple-phase power electronics module, that distributes power across multiple separate phases, may have differences in power distribution, heat distribution, and heat dissipation that are not adequately addressed by the heat sink module of the '396 patent.

The power electronics module of the present disclosure solves one or more of the problems set forth above and/or other problems in the art.

### SUMMARY

A power electronics module, configured to control electrical power in multiple phases, may include a capacitor with a casing having multiple panels defining a box-shaped enclosure. The power electronics module may include one or more heat sinks disposed on an exterior of the casing, the one or more heat sinks having first planar surfaces, disposed on one or more of the panels, and second planar surfaces opposite the first planar surfaces. The power electronics module may include a plurality of power switching modules electrically connected to the capacitor and disposed on the second planar surfaces of the one or more heat sinks, the plurality of power switching modules configured to control electrical power flow in respective phases of the multiple phases.

A power converter, configured to control electrical power in multiple phases, may include a capacitor with a casing having multiple panels defining an enclosure. The power converter may include one or more heat sinks disposed on an exterior of the casing. The power converter may include a plurality of power switching modules electrically connected to the capacitor and disposed on respective planar surfaces of the one or more heat sinks, the plurality of power switching modules configured to control electrical power flow in respective phases of the multiple phases.

A machine may include a power source configured to output electrical power and a power electronics module electrically coupled to the power source and configured to control electrical power in multiple phases. The power electronics module may include a capacitor with a casing having multiple panels defining an enclosure. The power electronics module may include one or more heat sinks disposed on an exterior of the casing. The power electronics module may include a plurality of power switching modules, disposed on the one or more heat sinks, configured to control electrical power flow in respective phases of the multiple phases. The power electronics module may include a plurality of controllers configured to control respective power switching modules of the plurality of power switching modules. The power electronics module may include a plurality of bus bars electrically connecting the respective power switching modules to the capacitor.

### BRIEF DESCRIPTION OF THE DRAWINGS

FIG. 1 is a perspective view of an example machine.

FIG. 2 is a block diagram illustrating an example power electronics module.

FIG. 3 is a perspective view of an example power electronics module.

FIG. 4 is an exploded view of the power electronics module of FIG. 3.

FIG. 5 is a perspective view of an example power electronics module.

FIG. 6 is an exploded view of the power electronics module of FIG. 5.

FIG. 7 is a perspective view of an example heat sink.

### DETAILED DESCRIPTION

This disclosure relates to a power electronics module, which is applicable to any electrical machine or system. For example, the electrical machine or system may be an electric vehicle, a diesel-electric machine, a battery-electric machine, or a renewable energy system, among other examples.

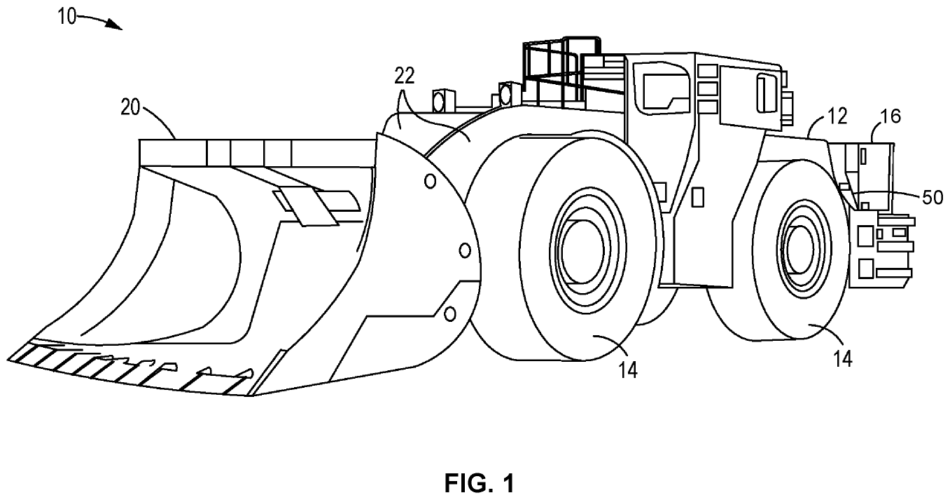

FIG. 1 is a perspective view of an example machine 10. The machine 10 may be a work machine. For example, the machine 10 may perform earth moving, excavation, or another operation associated with an industry, such as mining. As an example, as illustrated in FIG. 1, the machine 10 is a load-haul-dump (LHD) loader. However, the machine 10 may be another type of machine, such as a compactor machine, a paving machine, a cold planer, a grading machine, a backhoe loader, a wheel loader, a harvester, an excavator, a motor grader, a skid steer loader, a tractor, a dozer, an underground articulated truck, or an off-highway truck, among other examples. The machine 10 may be a diesel-electric machine (e.g., that includes a diesel engine and electrical systems, such as generators, to convert power from the engine to electricity for propulsion and/or operation of the machine 10). Additionally, or alternatively, the machine 10 may be a battery-electric machine (e.g., that uses electric power stored in one or more batteries for propulsion and/or operation of the machine 10).

The machine 10 may include a frame 12 supported by a plurality of ground-engaging members 14, which are illustrated as wheels. Additionally, or alternatively, the ground-engaging members 14 may include track assemblies, skids, or the like. The ground-engaging members 14 are used to propel the machine 10 over a work surface.

The machine 10 includes a power source 16 configured to output electrical power, which may be used to power the ground-engaging members 14. For example, the power source 16 may provide power to an electric motor (not shown) of the machine 10 and/or one or more machine accessories (e.g., a heating, ventilation, and air conditioning (HVAC) system). The electric motor may be a multiple-phase (e.g., a three-phase) motor, such as an induction motor. The power source 16 may include an internal combustion engine (e.g., a diesel engine) and an electrical generator coupled to the engine (e.g., in a diesel-electric machine configuration). Additionally, or alternatively, the power source 16 may include one or more batteries (e.g., in a battery-electric machine configuration). The machine includes a power electronics module 50 connected to the power source 16. The power electronics module 50 is configured to provide control and/or conversion of electrical power in one or more electrical systems of the machine 10. The power electronics module 50 may be a power converter. For example, the power electronics module 50 may be configured as an alternating current (AC) inverter or a direct current (DC) converter, among other examples.

The machine 10 may further include an implement 20 mounted to the frame 12 that may be used to manipulate and/or transport work material at a worksite. For example, the implement 20 may be mounted to the frame 12 by a pair of lift arms 22. The implement 20 may include a bucket, as shown. In some implementations, the power source 16 may provide power to the implement 20 (e.g., via a hydraulic system of the machine 10).

As indicated above, FIG. 1 is provided as an example. Other examples may differ from what is described with regard to FIG. 1.

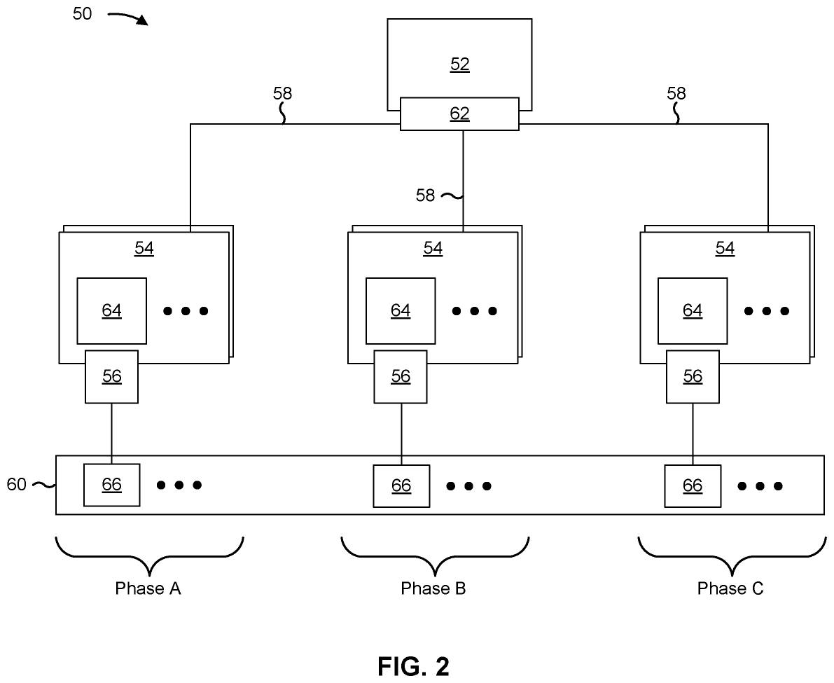

FIG. 2 is a block diagram illustrating an example power electronics module 50. The power electronics module 50 is a multiple-phase (e.g., three-phase) power electronics module. That is, the power electronics module 50 is configured to control electrical power in multiple phases (e.g., multiple sinusoidal voltages or currents separated by an angle of 120 degrees). For example, the power electronics module 50 may be configured to control the flow of electrical power in a multiple-phase electrical system. As an example, the power electronics module 50 may be configured to perform multiple-phase power conversion operations.

The power electronics module 50 includes a capacitor 52, a plurality of power switching modules 54, a plurality of controllers 56, a plurality of bus bars 58, and/or a power supply module 60. The power module 50 may include additional circuitry components, electronics, sensors (e.g., current sensors), and/or electrical wiring that facilitate the operation of the power electronics module 50.

The capacitor 52 may be electrically connected to the power source 16 (directly or indirectly). The capacitor 52 may be configured to reduce ripple in a DC input and/or to isolate a DC link from transients, among other examples. The capacitor 52 may be a high-temperature and/or high-density capacitor. In an example, the capacitor 52 may be a polypropylene film capacitor. The capacitor 52 includes a set of terminals 62 that enable electrical connection of the capacitor 52 to a circuit.

A power switching module 54 (which can also be referred to as a “power semiconductor module”) may include one or more power switching devices 64 (which can also be referred to as “power semiconductor devices”) and associated components in a package. A power switching device 64 is configured to control electrical power flow (e.g., the flow of electrical current) in the power electronics module 50. For example, a power switching device 64 may be configured to switch between an on or closed state, in which the power switching device 64 allows electrical power flow, and an off or open state in which the power switching device 64 prevents electrical power flow. A power switching device 64 may include an insulated gate bipolar transistor (IGBT), a thyristor, a power diode, or a metal oxide semiconductor field effect transistor (MOSFET), among other examples. The power switching modules 54 are electrically connected to the capacitor 52 (e.g., to the terminals 62 of the capacitor 52). For example, the bus bars 58 (e.g., DC bus bars) electrically connect respective power switching modules 54 to the capacitor 52. The bus bars 58 may include laminated bus bars and/or monolithic bus bars.

Each power switching module 54 is communicatively connected to and controlled by a respective controller 56 (e.g., that may be mounted on the power switching module 54). For example, the one or more power switching devices 64 of a power switching module 54 are each communicatively connected to and controlled by a controller 56 for that power switching module 54. A controller 56 may be configured to generate control signals, applied at a gate terminal of a power switching device 64, for switching the power switching device 64 between an on state and an off state. Accordingly, a controller 56 may be a gate drive controller, a gate drive board, or the like. A controller 56 may include one or more integrated circuits and associated circuitry mounted on a circuit board (e.g., a printed circuit board). The power supply module 60 includes a plurality of power supplies 66. The power supplies 66 are electrically connected to and configured to power respective controllers 56.

The power electronics module 50 may include respective groups of components for each of the phases of the multiple phases of electrical power. For example, the power electronics module 50 may include, for a first phase (which may be denoted as Phase A), a first set of power switching modules 54, a first set of controllers 56, and a first set of bus bars 58; the power electronics module 50 may include, for a second phase (which may be denoted as Phase B), a second set of power switching modules 54, a second set of controllers 56, and a second set of bus bars 58; and the power electronics module 50 may include, for a third phase (which may be denoted as Phase C), a third set of power switching modules 54, a third set of controllers 56, and a third set of bus bars 58.

Accordingly, the power switching modules 54 are configured to control electrical power flow in respective phases of the multiple phases of electrical power. As an example, the power electronics module 50 may include one or more power switching modules 54 per phase (e.g., two or four power switching modules 54 per phase). For example, one or more first power switching modules 54 may control the flow of electrical power in a first phase, one or more second power switching modules 54 may control the flow of electrical power in a second phase, and one or more third power switching modules 54 may control the flow of electrical power in a third phase.

As indicated above, FIG. 2 is provided as an example. Other examples may differ from what is described with regard to FIG. 2.

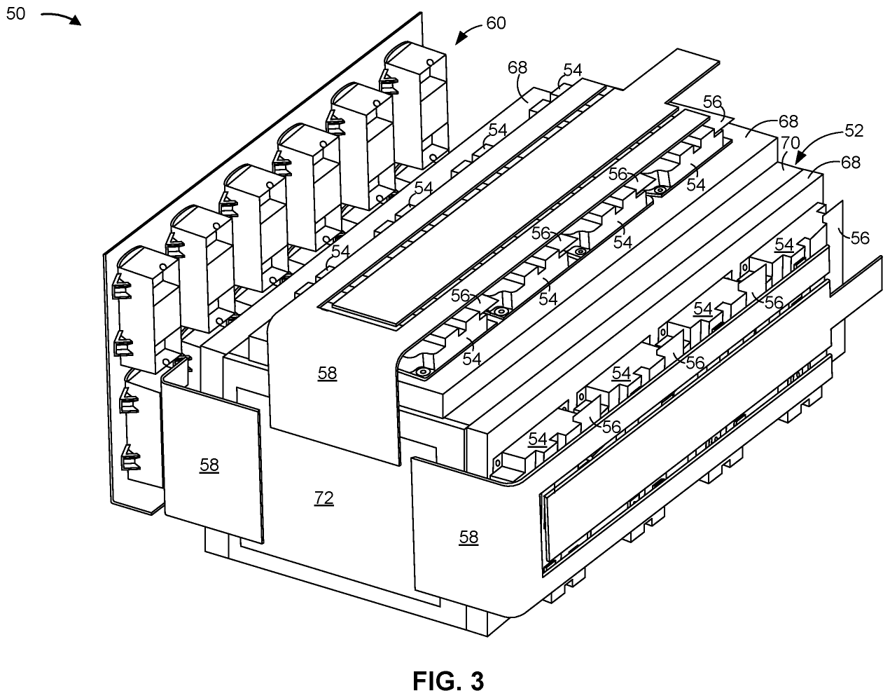

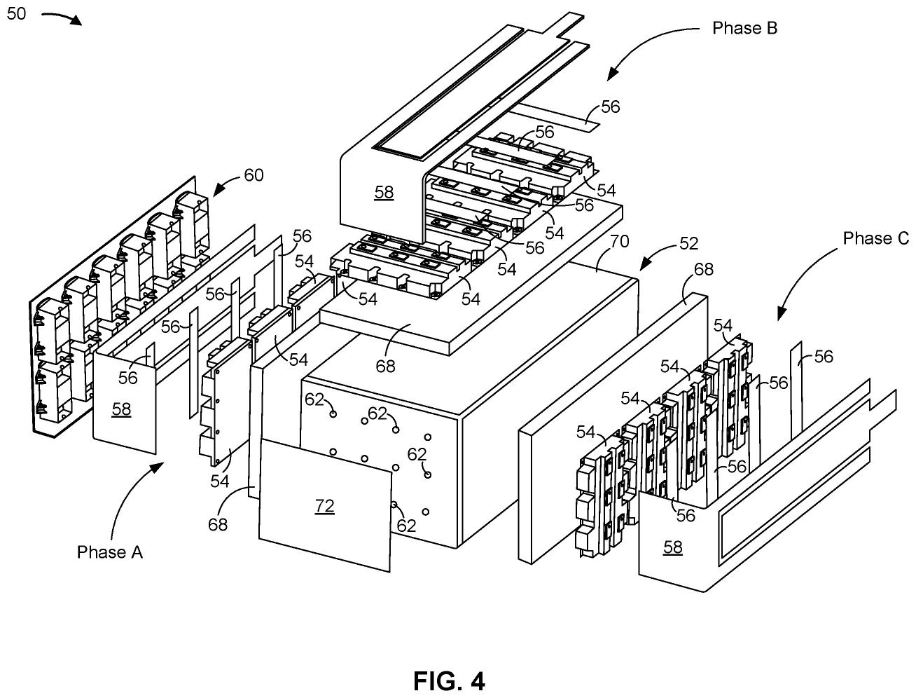

FIG. 3 is a perspective view of an example power electronics module 50, and FIG. 4 is an exploded view of the power electronics module 50 of FIG. 3. As shown, the power electronics module 50 includes the capacitor 52, the power switching modules 54, the controllers 56, the bus bars 58, and/or the power supply module 60 described herein. Additionally, the power electronics module 50 includes a plurality of heat sinks 68 (e.g., two, three, or four heat sinks 68). These components of the power electronics module 50 are assembled together in the configuration shown, and may be contained within a housing (not shown). The power electronics module 50 may be arranged in a vertical orientation, a horizontal orientation, or another orientation in the housing (e.g., an enclosure), and interface connections (e.g., electrical connections, mechanical connections, and/or cooling connections) may be configured to accommodate the orientation of the power electronics module 50 (e.g., different configurations of the interface connections may be used for different orientations). In the configuration of the power electronics module shown in FIGS. 3-4, the bus bars 58 may include laminated bus bars.

The capacitor 52 may have a casing 70 that surrounds internal elements of the capacitor 52. The casing 70 provides mechanical support and/or insulation for the capacitor 52. The casing 70 may be composed of plastic, metal, and/or ceramic, among other examples. The casing 70 has multiple panels (e.g., substantially flat, planar sections of the casing 70) that are joined along their edges to define an enclosure (e.g., a box-shaped enclosure). The panels may also be referred to as “walls,” “faces,” or “facets” of the casing 70. As shown, the terminals 62 of the capacitor 52 may be accessible at an end panel of the casing 70. In some implementations, the power electronics module 50 may include an additional bus bar 72 (e.g., mounted on the end panel) that electrically connects the terminals 62 to the bus bars 58.

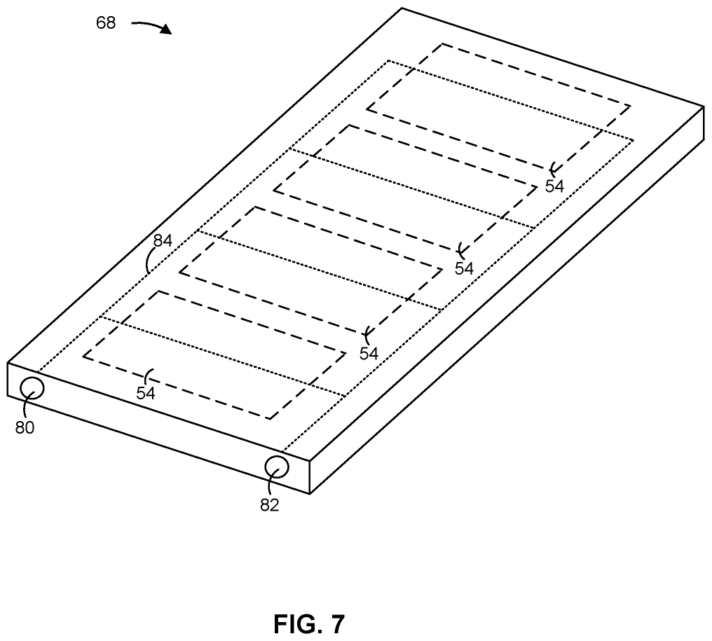

A heat sink 68 may include any heat-exchanging component configured to dissipate heat in the power electronics module 50. A heat sink 68 may be a fluid-cooled (e.g., liquid-cooled) heat sink, as described further in FIG. 7. For example, a heat sink 68 may be in a fluid cooling circuit. In some implementations, the heat sinks 68 may be in respective fluid cooling circuits (e.g., the heat sinks 68 are configured in parallel). Alternatively, the heat sinks 68 may be in a single cooling circuit (e.g., the heat sinks 68 are configured in series).

A heat sink 68 may have an overall flat, planar shape. For example, a heat sink 68 may include a plate having one or more internal fluid passageways defined therein. In some examples, the heat sink 68 may further include a set of internal fins that are positioned within (e.g., extend into) the fluid passageways.

The heat sinks 68 are disposed on an exterior of the casing 70 (e.g., on one or more of the panels) such that the heat sinks 68 are in direct contact with the casing 70. For example, the heat sinks 68 may be mounted to the exterior of the casing 70 by fasteners, such as bolts. In this way, the heat sinks 68 are configured to dissipate heat from the capacitor 52.

As shown, the heat sinks 68 may be disposed on respective panels of the casing 70 (e.g., panels other than the end panel where the terminals 62 are located), and the power switching modules 54 may be disposed on respective heat sinks 68 (e.g., in stacked configurations). One or more power switching modules 54 may be mounted to a heat sink 68 by fasteners (e.g., bolts) that are received in apertures (e.g., threaded apertures) of the heat sink 68. As an example, first planar surfaces of the heat sinks 68 may be disposed on the respective panels (which also have planar surfaces), and the power switching modules 54 may be disposed on second planar surfaces of the heat sinks 68 (opposite the first planar surfaces). The planar surfaces of the heat sinks 68 provide large thermal interface areas between the heat sinks 68 and the capacitor 52 as well as between the heat sinks 68 and the power switching modules 54.

In this way, each heat sink 68 is configured to dissipate heat from the power switching module(s) 54 for a respective phase of the multiple phases of electrical power. For example, as shown, the power electronics module 50 includes three heat sinks 68 (e.g., one for each of three phases), with a first heat sink 68 disposed on a first panel of the casing 70 and one or more first power switching modules 54 (for a first phase, Phase A) disposed on the first heat sink 68, a second heat sink 68 disposed on a second panel of the casing 70 and one or more second power switching modules 54 (for a second phase, Phase B) disposed on the second heat sink 68, and a third heat sink 68 disposed on a third panel of the casing 70 and one or more third power switching modules 54 (for a third phase, Phase C) disposed on the third heat sink 68. Alternatively, the power electronics module 50 may have a two-phase configuration that includes two heat sinks 68 and corresponding power switching modules 54 disposed on two panels of the casing 70, or a four-phase configuration that includes four heat sinks 68 and corresponding power switching modules 54 disposed on four panels of the casing 70. The heat sinks 68 may also dissipate heat from the controllers 56 and/or the bus bars 58, which may conduct heat through the power switching modules 54.

As indicated above, FIGS. 3-4 are provided as an example. Other examples may differ from what is described with regard to FIGS. 3-4.

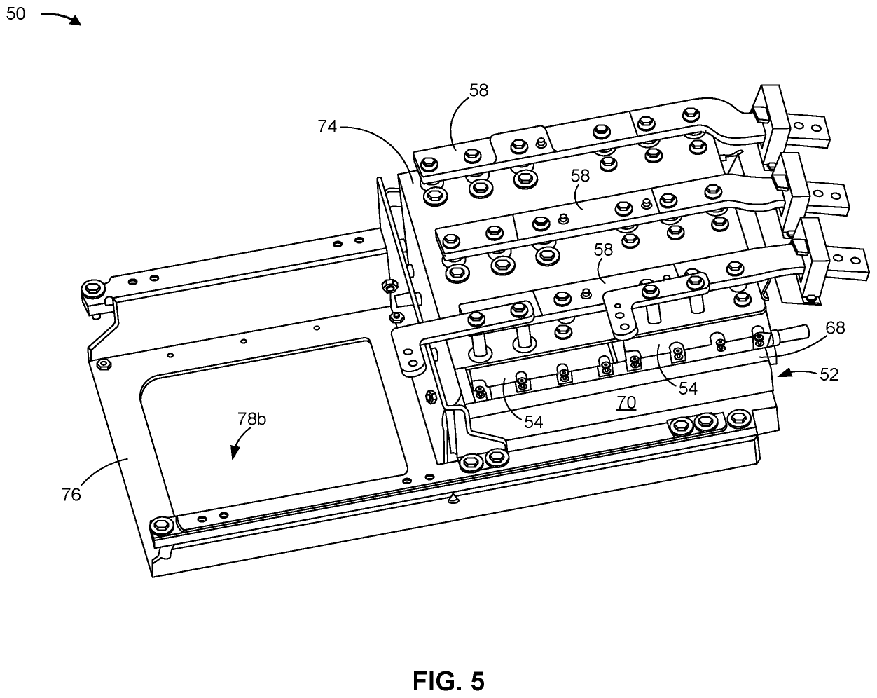

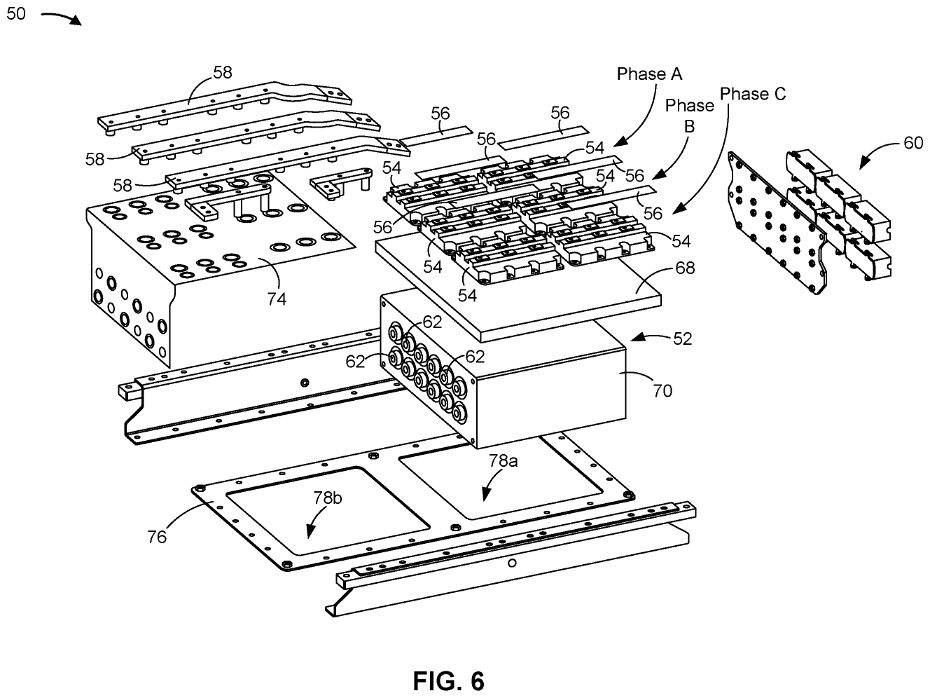

FIG. 5 is a perspective view of an example power electronics module 50, and FIG. 6 is an exploded view of the power electronics module 50 of FIG. 5. The power electronics module 50 shown in FIGS. 5-6 is an alternative to the power electronics module 50 shown in FIGS. 3-4. As shown, the power electronics module 50 includes the capacitor 52, the power switching modules 54, the controllers 56, the bus bars 58, and/or the power supply module 60 described herein. Additionally, the power electronics module 50 includes a heat sink 68. The heat sink 68 may be a single heat sink 68, or the single heat sink 68 may be broken up into multiple heat sinks 68 that are functionally similar to the single heat sink 68 (e.g., the heat sink 68 may include one or more heat sinks). These components of the power electronics module 50 are assembled together in the configuration shown, and may be contained within a housing (not shown). The power electronics module 50 may be arranged in a vertical orientation, a horizontal orientation, or another orientation in the housing (e.g., an enclosure), and interface connections (e.g., electrical connections, mechanical connections, and/or cooling connections) may be configured to accommodate the orientation of the power electronics module 50 (e.g., different configurations of the interface connections may be used for different orientations). In the configuration of the power electronics module shown in FIGS. 5-6, the bus bars 58 may include monolithic bus bars.

The capacitor 52 may have a casing 70 defined by multiple panels, and the terminals 62 of the capacitor 52 may be accessible at an end panel of the casing 70, as described herein. In some implementations, the power electronics module 50 may include an additional bus bar 74 (e.g., a laminated bus bar) that electrically connects the terminals 62 to the bus bars 58.

The heat sink 68 is disposed on an exterior of the casing 70, as described herein. As shown, the heat sink 68 may be disposed on a single panel of the casing 70 (e.g., a panel other than the end panel where the terminals 62 are located), and the power switching modules 54 may be disposed on the single heat sink 68 (e.g., in stacked configurations). For example, a first planar surface of the heat sink 68 may be disposed on the single panels (which also has a planar surface), and the power switching modules 54 may be disposed on a second planar surface of the heat sink 68 (opposite the first planar surface).

In this way, the heat sink 68 is configured to dissipate heat from the power switching modules 54 for the multiple phases of electrical power. For example, as shown, the power electronics module 50 includes a single heat sink 68 (e.g., encompassing three phases) disposed on a panel of the casing 70, with one or more first power switching modules 54 (for a first phase, Phase A) disposed on the single heat sink 68, one or more second power switching modules 54 (for a second phase, Phase B) disposed on the single heat sink 68, and one or more third power switching modules 54 (for a third phase, Phase C) disposed on the single heat sink 68. Alternatively, the power electronics module 50 may have a two-phase configuration that includes power switching modules 54 for two phases disposed on the heat sink 68, or a four-phase configuration that includes power switching modules 54 for four phases disposed on the heat sink 68.

As shown, the power electronics module 50 may be mounted in a frame 76. The frame may define one or more module receptacles 78. For example, the power electronics module 50 may be mounted in a first module receptacle 78a of the frame 76. In some implementations, an additional power electronics module 50 (not shown) may be mounted in a second module receptacle 78b of the frame 76. The additional power electronics module 50 may be electrically connected to the power electronics module 50 for increased power.

As indicated above, FIGS. 5-6 are provided as an example. Other examples may differ from what is described with regard to FIGS. 5-6.

FIG. 7 is a perspective view of an example heat sink 68. As described herein, power switching modules 54 may be disposed on the heat sink 68. As shown, the heat sink 68 has a fluid inlet 80, a fluid outlet 82, and a fluid passageway 84 between the fluid inlet 80 and the fluid outlet 82. The fluid passageway 84 may be configured in a path that passes across each of the power switching modules 54. For example, the path may cross the power switching modules 54 in parallel (as shown) or in series (e.g., a serpentine path). The fluid inlet 80, the fluid outlet 82, and the fluid passageway 84 may be part of a fluid cooling circuit. For example, cool fluid (e.g., water or a liquid coolant) may be supplied at the fluid inlet 80, may circulate through the fluid passageway 84 where the fluid absorbs heat, and may exit through the fluid outlet 82. The fluid cooling circuit may include a cool fluid supply (e.g., a fluid pump) to supply the cool fluid (e.g., fresh cool fluid or previously-heated fluid that has been cooled) to the heat sink 68.

As indicated above, FIG. 7 is provided as an example. Other examples may differ from what is described with regard to FIG. 7.

### INDUSTRIAL APPLICABILITY

The power electronics module 50 described herein may be used with any machine or system to provide control and/or conversion of electrical power. For example, the power electronics module 50 may be used in a diesel-electric machine, a battery-electric machine, or a renewable energy system, among other examples. Without efficient thermal management, heat generated in the power electronics module 50 may harm the capacitor 52, the power switching modules 54, and/or the controllers 56. For example, excessive heat may reduce a capacitance and/or a power density of the capacitor 52. Accordingly, a performance of the power electronics module 50 may suffer due to excessive heat.

The power electronics module 50 described herein has improved thermal management capabilities. In particular, the arrangement of the heat sink(s) 68 between the casing 70 of the capacitor 52 and the power switching modules 54 provides heat dissipation for both the capacitor 52 and the power switching modules 54 while also efficiently minimizing heat that is transferred from the power switching modules 54 to the capacitor 52. Accordingly, the heat sink(s) 68 prevent damage to the capacitor 52 and the power switching modules 54, and improve the capacitance and/or power density of the capacitor 52. Furthermore, the planar surfaces of the heat sink(s) 68 provide large thermal interface areas between the heat sink(s) 68, the capacitor 52, and the power switching modules 54 that promote efficient heat dissipation from the power electronics module 50. Moreover, the stacked configuration of the heat sink(s) 68 with components associated with multiple phases of electrical power provides balanced and efficient heat dissipation for a multiple-phase power electronics module 50. In this way, the power electronics module 50 has improved performance, thereby improving the performance of a machine or system that includes the power electronics module 50.

What is claimed is:

1. A power electronics module configured to control electrical power in multiple phases, comprising:
a capacitor with a casing having multiple panels defining a box-shaped enclosure;
one or more heat sinks disposed on an exterior of the casing,
the one or more heat sinks having first planar surfaces, disposed on one or more of the panels, and second planar surfaces opposite the first planar surfaces; and
a plurality of power switching modules electrically connected to the capacitor and disposed on the second planar surfaces of the one or more heat sinks,
the plurality of power switching modules configured to control electrical power flow in respective phases of the multiple phases.

2. The power electronics module of claim 1, wherein the one or more heat sinks comprise a plurality of heat sinks disposed on respective panels of the multiple panels, and
wherein the plurality of power switching modules are disposed on respective heat sinks of the plurality of heat sinks.

3. The power electronics module of claim 2, wherein a first heat sink, of the plurality of heat sinks, is disposed on a first panel, of the multiple panels, and a first power switching module, of the plurality of power switching modules, is disposed on the first heat sink,
wherein a second heat sink, of the plurality of heat sinks, is disposed on a second panel, of the multiple panels, and a second power switching module, of the plurality of power switching modules, is disposed on the second heat sink, and
wherein a third heat sink, of the plurality of heat sinks, is disposed on a third panel, of the multiple panels, and a third power switching module, of the plurality of power switching modules, is disposed on the third heat sink.

4. The power electronics module of claim 1, wherein the one or more heat sinks are disposed on a single panel of the multiple panels.

5. The power electronics module of claim 4, wherein the one or more heat sinks comprise a single heat sink, and
wherein a first power switching module, a second power switching module, and a third power switching module, of the plurality of power switching modules, are disposed on the single heat sink.

6. The power electronics module of claim 1, further comprising:
a plurality of controllers configured to control respective power switching modules of the plurality of power switching modules.

7. The power electronics module of claim 6, wherein the plurality of controllers are disposed on the respective power switching modules.

8. The power electronics module of claim 6, further comprising:
a power supply module comprising a plurality of power supplies,
wherein the plurality of power supplies are electrically connected to respective controllers of the plurality of controllers.

9. The power electronics module of claim 1, wherein the power electronics module is configured as an alternating current (AC) inverter or a direct current (DC) converter.

10. A power converter configured to control electrical power in multiple phases, comprising:
a capacitor with a casing having multiple panels defining an enclosure;
one or more heat sinks disposed on an exterior of the casing; and
a plurality of power switching modules electrically connected to the capacitor and disposed on respective planar surfaces of the one or more heat sinks,
the plurality of power switching modules configured to control electrical power flow in respective phases of the multiple phases.

11. The power converter of claim 10, wherein the one or more heat sinks comprise a plurality of heat sinks disposed on respective panels of the multiple panels, and
wherein the plurality of power switching modules are disposed on respective heat sinks of the plurality of heat sinks.

12. The power converter of claim 10, wherein the one or more heat sinks are disposed on a single panel of the multiple panels.

13. The power converter of claim 10, wherein the multiple phases include three phases.

14. The power converter of claim 10, wherein a power switching module, of the plurality of power switching modules, includes one or more insulated gate bipolar transistors.

15. The power converter of claim 10, further comprising:
a plurality of bus bars electrically connecting the respective power switching modules, of the plurality of power switching modules, to the capacitor.

16. A machine, comprising:
a power source configured to output electrical power; and
a power electronics module electrically coupled to the power source and configured to control electrical power in multiple phases, comprising:
a capacitor with a casing having multiple panels defining an enclosure;
one or more heat sinks disposed on an exterior of the casing;
a plurality of power switching modules, disposed on the one or more heat sinks, configured to control electrical power flow in respective phases of the multiple phases;
a plurality of controllers configured to control respective power switching modules of the plurality of power switching modules; and
a plurality of bus bars electrically connecting the respective power switching modules to the capacitor.

17. The machine of claim 16, wherein the one or more heat sinks comprise a plurality of heat sinks disposed on respective panels of the multiple panels, and
wherein the plurality of power switching modules are disposed on respective heat sinks of the plurality of heat sinks.

18. The machine of claim 17, wherein the plurality of heat sinks are in respective fluid cooling circuits.

19. The machine of claim 16, wherein the one or more heat sinks are disposed on a single panel of the multiple panels.

20. The power electronics module of claim 16, wherein a heat sink, of the one or more heat sinks, has a fluid inlet, a fluid outlet, and a fluid passageway between the fluid inlet and the fluid outlet.
